(19) United States
(12) Patent Application Publication
(10) Pub. No.: US 2024/0196679 A1
(43) Pub. Date: Jun. 13, 2024

(54) DISPLAY PANEL AND DISPLAY APPARATUS

(71) Applicant: WUHAN CHINA STAR OPTOELECTRONICS SEMICONDUCTOR DISPLAY TECHNOLOGY CO., LTD., Wuhan (CN)

(72) Inventors: Yanjun GUAN, Wuhan (CN); Gui CHEN, Wuhan (CN); Jianhong SHI, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 18/558,244

(22) Filed: Oct. 31, 2023

Related U.S. Application Data
(63) Continuation of application No. PCT/CN2023/103566, filed on Jun. 29, 2023.

(30) Foreign Application Priority Data
Dec. 12, 2022 (CN) 202211596905.0

(51) Int. Cl. H10K 59/131

(52) U.S. Cl. CPC H10K 59/131

(57) ABSTRACT

A display panel and a display apparatus. The display panel includes a display region, an opening region, and a transition region between the display region and the opening region, the display panel includes: a substrate; a first metal layer on a side of the substrate, wherein the first metal layer comprises one or more first scanning lines; a second metal layer on a side of the first metal layer away from the substrate; and a source drain layer arranged on a side of the second metal layer away from the first metal layer.

### CROSS-REFERENCE TO RELATED APPLICATIONS

This application is a continuation application of International Application No. PCT/CN2023/103566, filed on Jun. 29, 2023, which claims priority to Chinese Application No. 202211596905.0, filed on Dec. 12, 2022. The disclosures of the above applications are incorporated herein by reference in their entireties.

### FIELD

The present disclosure relates to display technologies, and in particular to a display panel and a display apparatus.

### BACKGROUND

With the development of display technology, in order to increase a screen-to-body ratio of conventional display devices, an opening may be formed on the display devices and electronic components are arranged in opening regions, in which case bezels are not needed, so that bezels of display panels can be reduced and the screen-to-body ratio is increased. However, in a display device, since there are no pixels in an opening region, a voltage drop of a scanning line of pixels in a row where the opening region is located is less than a voltage drop of a scanning line of pixels in a row where a non-opening region is located. Thus, during display, non-uniform display may be caused due to an issue of different voltage drops of scanning lines in rows where the opening region and the non-opening region are respectively located. As shown in FIG. 1, FIG. 2, and FIG. 3, (a) in FIG. 3 is a perspective view of a compensation unit, and (b) in FIG. 3 is an exploded view of the compensation unit. In order to solve a problem of non-uniform display, in a conventional display device 1, the compensation unit may be provided in a winding region 13 surrounding an opening region 12. By providing a power signal line 142 on a first source drain layer, the power signal line 142 and scanning line 141 of a second gate layer form capacitors, such that the voltage drop of the scanning line in a row where the opening region 12 is located is increased and non-uniform display is prevented. However, such design will cause the compensation unit to occupy too much area of the winding region 13. In order to keep windings of the data lines 143 off the opening region 12, the area of the winding region 13 has to be increased, resulting in a large width of the winding region 13 and then resulting in a large black edge between the opening region 12 and a display region 11.

Therefore, has there is a problem of a large black edge between the opening region and the display region in the conventional display device due to a fact that the compensation unit occupies a large area of the winding region.

### SUMMARY

A display panel and a display apparatus according to one or more embodiments of the present disclosure is directed to mitigate a problem of a large black edge between the opening region and the display region in the conventional display device due to a fact that the compensation unit occupies a large area of the winding region.

The present disclosure provides the following solutions.

A display panel according to one or more embodiments of the present disclosure includes a display region, an opening region, and a transition region between the display region and the opening region, the display panel including:
a substrate;
a first metal layer on a side of the substrate, the first metal layer including one or more first scanning lines;
a second metal layer on a side of the first metal layer away from the substrate; and
a source drain layer on a side of the second metal layer away from the first metal layer;
the transition region including an invalid pixel region and a winding region between the invalid pixel region and the opening region, the invalid pixel region being provided with a compensation unit, the compensation unit at least includes a compensation wiring on the second metal layer, and a projection of the compensation wiring on the substrate overlaps with a projection of at least one of the one or more first scanning lines on the substrate.

In some embodiments, the compensation unit further includes a power supply high-potential signal line, at least part of the power supply high-potential signal line is arranged on the second metal layer, and the power supply high-potential signal line is connected to the compensation wiring.

In some embodiments, the source drain layer includes a first source drain layer and a second source drain layer, the display panel further includes a first planarization layer, the second source drain layer is arranged on a side of the first source drain layer away from the second metal layer, the first planarization layer is arranged between the first source drain layer and the second source drain layer, the power supply high-potential signal line includes a first power supply high-potential signal line located on the second metal layer and a second power supply high-potential signal line located on the first source drain layer, the first power supply high-potential signal line is connected to the compensation wiring, and the second power supply high-potential signal line passes through a via hole of the first planarization layer and is then connected to the compensation wiring.

In some embodiments, the display panel further includes an interlayer insulating layer, and the interlayer insulating layer is arranged between the first source drain layer and the second metal layer. The compensation unit further includes:
a second scanning line arranged on the first metal layer and insulated from the first scanning line;
an initialization signal line including a first initialization signal line and a second initialization signal line, wherein the first initialization signal line is arranged on the second metal layer, the second initialization signal line is arranged on the first source drain layer, and the second initialization signal line passes through a via hole of the interlayer insulating layer and is then connected to the first initialization signal line;
a light-emitting control signal line arranged on the first metal layer; and
a first data line arranged on the second source drain layer.

In some embodiments, the display panel further includes a second data line arranged in the winding region, the second data line includes a first part arranged on the second source drain layer and a second part arranged on the first source drain layer, and the first part passes through a via hole of the first planarization layer and is then connected to the second part.

In some embodiments, the display panel further includes a first gate insulating layer, a second gate insulating layer, and an interlayer insulating layer, the first gate insulating layer is arranged between the first metal layer and the substrate, the second gate insulating layer is arranged between the first metal layer and the second metal layer, the interlayer insulating layer is arranged between the second metal layer and the first source drain layer, the second data line further includes a third part and a fourth part, the third part is arranged on the second metal layer, the fourth part is arranged on the first metal layer, the second part passes through a via hole of the interlayer insulating layer and is then connected to the third part, and the third part passes through a via hole of the second gate insulating layer and is then connected to the fourth part.

In some embodiments, the display region is provided with display pixels, the invalid pixel region is provided with invalid pixels, and the invalid pixels are arranged between the display pixels and the compensation units.

In some embodiments, the display panel further includes an active layer, the active layer includes an active pattern, and the projection area of the active pattern in the invalid pixel on the substrate is larger than the projection area of the active pattern in the compensation unit on the substrate.

In some embodiments, the display region is arranged around the opening region, and the shape of the opening region is at least one of a track shape, a circular shape, or a square shape.

In some embodiments, along an arrangement direction of at least one of the one or more first scanning lines, the compensation units are arranged respectively on two sides of the opening region.

In some embodiments, the display panel includes a plurality of rows of first scanning lines, and in the transition region, the overlapping areas between the projections of the first scanning lines of different rows on the substrate and the projections of the compensation wirings on the substrate are different.

In some embodiments, the display panel includes a plurality of rows of first scanning lines, and in the transition region, the number of compensation units corresponding to first scanning lines of different rows are different.

In addition, embodiments of the present disclosure provide a display apparatus. The display apparatus includes a display panel and an electronic component. The display panel includes a display region, an opening region, and a transition region located between the display region and the opening region, and the display panel includes:
a substrate;
a first metal layer arranged on one side of the substrate, wherein the first metal layer includes a plurality of first scanning lines;
a second metal layer arranged on a side of the first metal layer away from the substrate;
and
a source drain layer arranged on a side of the second metal layer away from the first metal layer.

The transition region includes an invalid pixel region and a winding region, the winding region is arranged between the invalid pixel region and the opening region, the invalid pixel region is provided with compensation units, each compensation unit at least includes a compensation wiring arranged on the second metal layer, and the projection of the compensation wiring on the substrate overlaps with the projection of the first scanning line on the substrate.

In some embodiments, the compensation unit further includes a power supply high-potential signal line, at least part of the power supply high-potential signal line is arranged on the second metal layer, and the power supply high-potential signal line is connected to the compensation wiring.

In some embodiments, the source drain layer includes a first source drain layer and a second source drain layer, the display panel further includes a first planarization layer, the second source drain layer is arranged on a side of the first source drain layer away from the second metal layer, the first planarization layer is arranged between the first source drain layer and the second source drain layer, the power supply high-potential signal line includes a first power supply high-potential signal line located on the second metal layer and a second power supply high-potential signal line located on the first source drain layer, the first power supply high-potential signal line is connected to the compensation wiring, and the second power supply high-potential signal line passes through a via hole of the first planarization layer and is then connected to the compensation wiring.

In some embodiments, the display panel further includes an interlayer insulating layer, and the interlayer insulating layer is arranged between the first source drain layer and the second metal layer. The compensation unit further includes:
a second scanning line arranged on the first metal layer and insulated from the first scanning line;
an initialization signal line including a first initialization signal line and a second initialization signal line, wherein the first initialization signal line is arranged on the second metal layer, the second initialization signal line is arranged on the first source drain layer, and the second initialization signal line passes through a via hole of the interlayer insulating layer and is then connected to the first initialization signal line;
a light-emitting control signal line arranged on the first metal layer; and
a first data line arranged on the second source drain layer.

In some embodiments, the display panel further includes a second data line arranged in the winding region, the second data line includes a first part arranged on the second source drain layer and a second part arranged on the first source drain layer, and the first part passes through a via hole of the first planarization layer and is then connected to the second part.

In some embodiments, the display panel further includes a first gate insulating layer, a second gate insulating layer, and an interlayer insulating layer, the first gate insulating layer is arranged between the first metal layer and the substrate, the second gate insulating layer is arranged between the first metal layer and the second metal layer, the interlayer insulating layer is arranged between the second metal layer and the first source drain layer, the second data line further includes a third part and a fourth part, the third part is arranged on the second metal layer, the fourth part is arranged on the first metal layer, the second part passes through a via hole of the interlayer insulating layer and is then connected to the third part, and the third part passes through a via hole of the second gate insulating layer and is then connected to the fourth part.

In some embodiments, the display region is provided with display pixels, the invalid pixel region is provided with invalid pixels, and the invalid pixels are arranged between the display pixels and the compensation units.

In some embodiments, the display panel further includes an active layer, the active layer includes an active pattern, and the projection area of the active pattern in the invalid pixel on the substrate is larger than the projection area of the active pattern in the compensation unit on the substrate.

Embodiments of the present disclosure provide a display panel and a display apparatus. The display panel includes a display region, an opening region, and a transition region located between the display region and the opening region. The display panel includes a substrate, a first metal layer, a second metal layer, and a source drain layer. The first metal layer is arranged on one side of the substrate; the first metal layer includes a plurality of first scanning lines; the second metal layer is arranged on a side of the first metal layer away from the substrate; and the source drain layer is arranged on a side of the second metal layer away from the first metal layer. The transition region includes an invalid pixel region and a winding region, the winding region is arranged between the invalid pixel region and the opening region, the invalid pixel region is provided with compensation units, each compensation unit at least includes a compensation wiring arranged on the second metal layer, and the projection of the compensation wiring on the substrate overlaps with the projection of the first scanning line on the substrate. In the present disclosure, by arranging the compensation units in the invalid pixel region, the compensation units can replace invalid pixels, thereby preventing an increased area of the transition region of the display panel; moreover, since the compensation units are not arranged in the winding region, data lines of the winding region can be arranged on different metal layers for winding, thereby reducing the area of the winding region, further reducing the area of the transition region, and reducing the area of a black edge between the display region and the opening region; in addition, since the compensation unit includes the compensation wiring arranged on the second metal layer, and the projection of the compensation wiring on the substrate overlaps with the projection of the first scanning line on the substrate, the voltage drop of a first scanning line in a row where the opening region is located can be compensated for, thereby preventing non-uniform display.

### BRIEF DESCRIPTION OF DRAWINGS

The following describes specific implementations of the present disclosure in detail with reference to the accompanying drawings, to make the technical solutions and other beneficial effects of the present disclosure obvious.

FIG. 1 shows a schematic diagram of a conventional display device.

FIG. 2 shows a perspective view of a conventional display device.

FIG. 3 shows a perspective view and an exploded view of a compensation unit of a conventional display device.

FIG. 4 shows a schematic diagram of a display panel according to one or more embodiments of the present disclosure.

FIG. 5 shows a sectional view of a display panel according to one or more embodiments of the present disclosure.

FIG. 6 shows a perspective view of a compensation unit of a display panel according to one or more embodiments of the present disclosure.

FIG. 7 shows an exploded view of the compensation unit in FIG. 6.

FIG. 8 shows a circuit diagram of a pixel drive circuit of a display panel according to one or more embodiments of the present disclosure.

FIG. 9 shows a perspective view of an invalid pixel of a display panel according to one or more embodiments of the present disclosure.

FIG. 10 shows a perspective view of an upper left side of an opening region of a display panel according to one or more embodiments of the present disclosure.

FIG. 11 shows a perspective view of a lower left side of an opening region of a display panel according to one or more embodiments of the present disclosure.

FIG. 12 shows a perspective view of an upper left side of an opening region of a conventional display device.

FIG. 13 shows a perspective view of a lower left side of an opening region of a conventional display device.

FIG. 14 shows a timing diagram of a pixel drive circuit according to one or more embodiments of the present disclosure.

FIG. 15 shows a perspective view of an actual product of a conventional display device.

FIG. 16 shows a perspective view of an actual product of a display panel according to one or more embodiments of the present disclosure.

FIG. 17 shows a comparison diagram of a capacitance change curve of one or more first scanning lines of a display panel according to one or more embodiments of the present disclosure and a capacitance change curve of one or more scanning lines in a conventional display device.

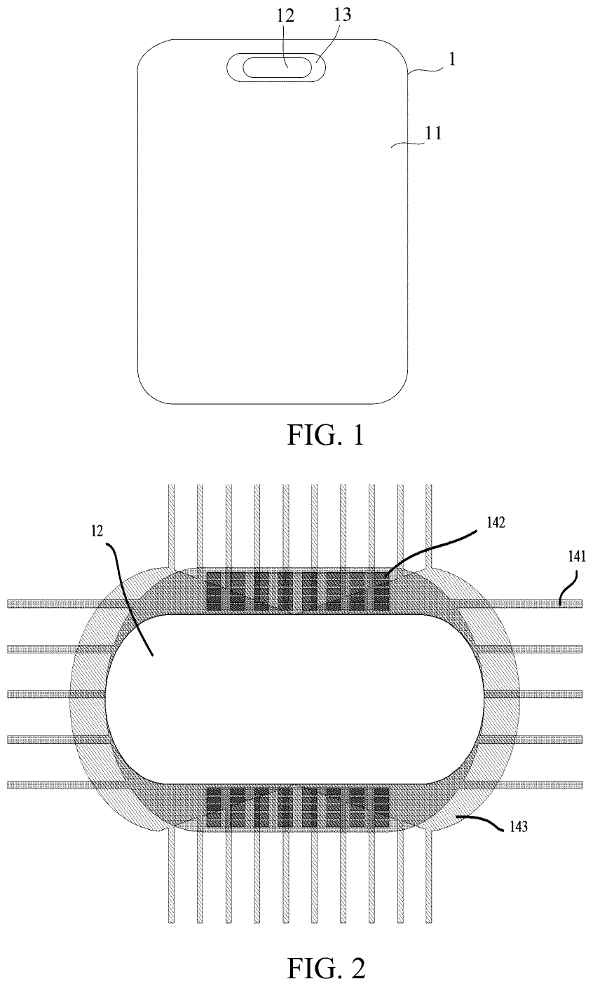

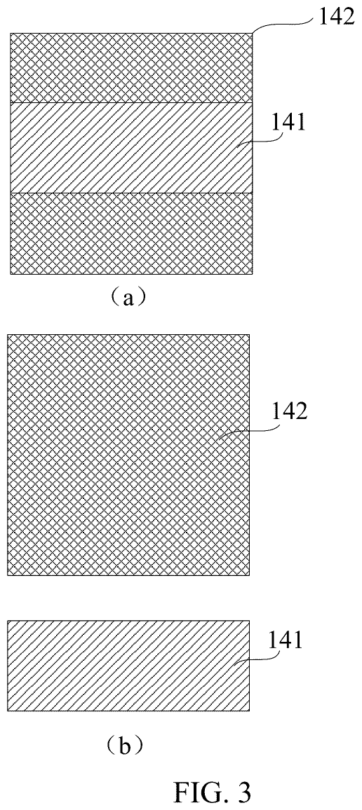

### DETAILED DESCRIPTION

The technical solutions of one or more embodiments of the present disclosure are clearly and completely described in the following with reference to the accompanying drawings of one or more embodiments of the present disclosure. Apparently, the described embodiments are merely some but not all of the embodiments of the present disclosure. All other embodiments obtained by a person skilled in the art based on one or more embodiments of the present disclosure without creative efforts shall fall within the protection scope of the present disclosure.

For a case that there is a problem of a large black edge between an opening region and a display region due to a fact that a compensation unit occupies a large area of a winding region in a conventional display device, a display panel and a display apparatus according to the present disclosure is used for mitigating the foregoing problem.

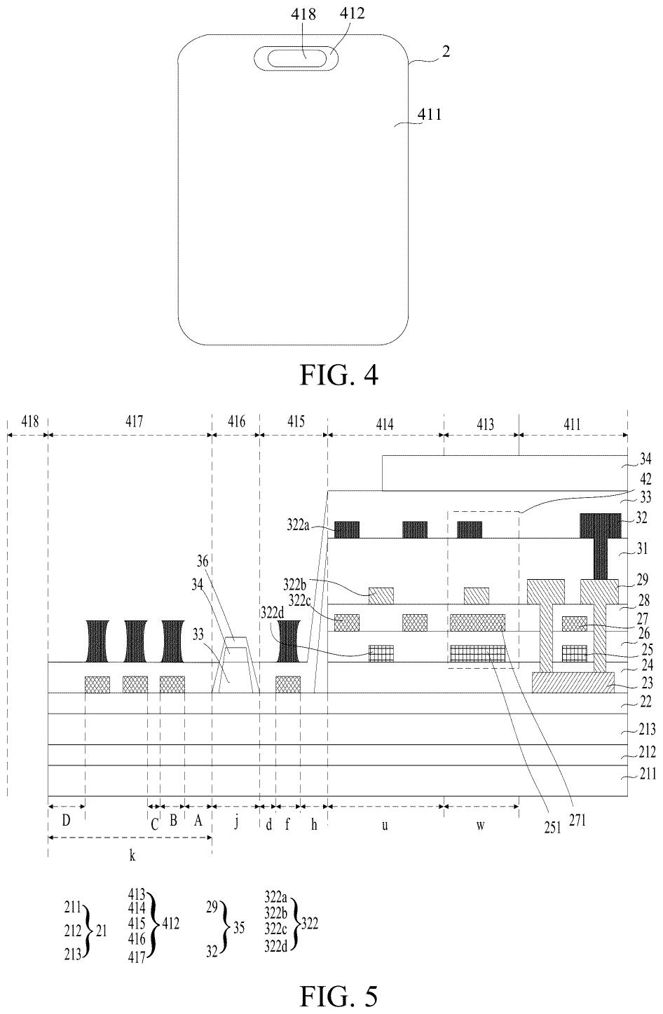

As shown in FIGS. 4 to 7, a display panel 2 according to one or more embodiments of the present disclosure includes a display region 411, an opening region 418, and a transition region 412 between the display region 411 and the opening region 418. The display panel 2 includes:
a substrate 21;
a first metal layer 25 on a side of the substrate 21, the first metal layer 25 including one or more first scanning lines 251;
a second metal layer 27 on a side of the first metal layer 25 away from the substrate 21; and
a source drain layer 35 on a side of the second metal layer 27 away from the first metal layer 25.

The transition region 412 includes an invalid pixel region 413 and a winding region 414. The winding region 414 is between the invalid pixel region 413 and the opening region 418. The invalid pixel region 413 is provided with a compensation unit 42. The compensation unit 42 at least includes a compensation wiring 271 on the second metal layer 27. A projection of the compensation wiring 271 on the substrate 21 overlaps with a projection of at least one of the one or more first scanning lines 251 on the substrate 21.

In a display panel according to one or more embodiments of the present disclosure, the compensation unit is in the invalid pixel region, so that the compensation unit can replace an invalid pixel, thereby preventing an increased area of the transition region of the display panel. Moreover, since the compensation unit is not arranged in the winding region, data lines in the winding region can be arranged on different metal layers for winding, thereby reducing the area of the winding region, further reducing the area of the transition region, and reducing area of a black edge between the display region and the opening region. In addition, since the compensation unit includes the compensation wiring on the second metal layer, and the projection of the compensation wiring on the substrate overlaps with the projection of the first scanning line on the substrate, thus voltage drop of a first scanning line in a row where the opening region is located can be compensated, thereby preventing non-uniform display.

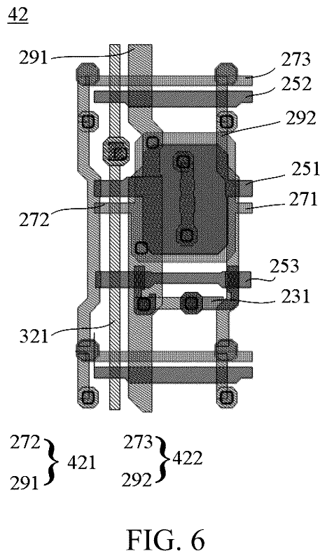

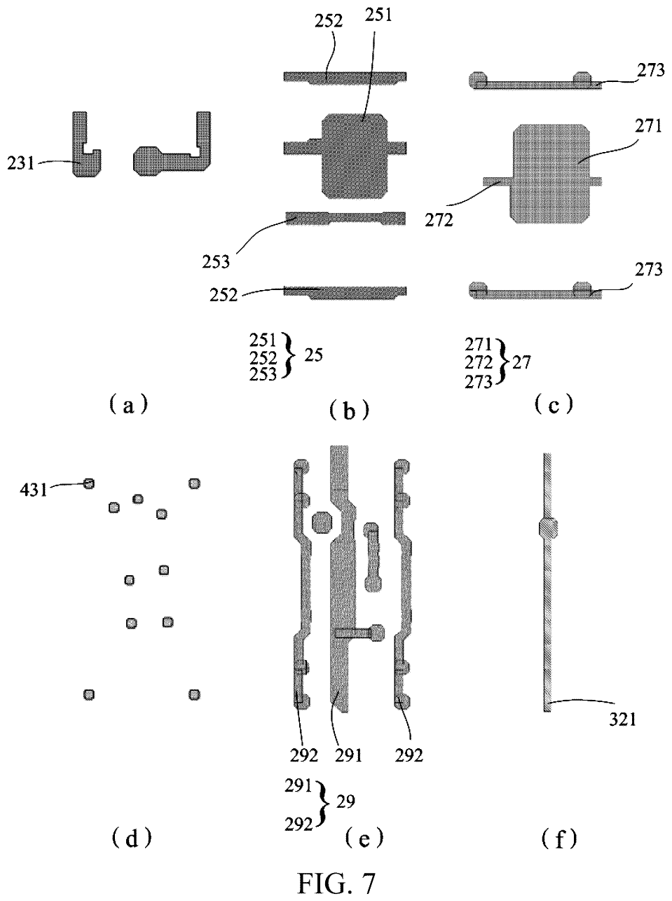

Specifically, FIG. 7 shows an exploded view of the compensation unit in FIG. 6. (a) in FIG. 7 shows an exploded view of an active layer in the compensation unit in FIG. 6. (b) in FIG. 7 shows an exploded view of the first metal layer in the compensation unit in FIG. 6. (c) in FIG. 7 shows an exploded view of the second metal layer in the compensation unit in FIG. 6. (d) in FIG. 7 shows an exploded view of via holes in the compensation unit in FIG. 6. (c) in FIG. 7 shows an exploded view of a first source drain layer in the compensation unit in FIG. 6. (f) in FIG. 7 shows an exploded view of a second source drain layer in the compensation unit in FIG. 6.

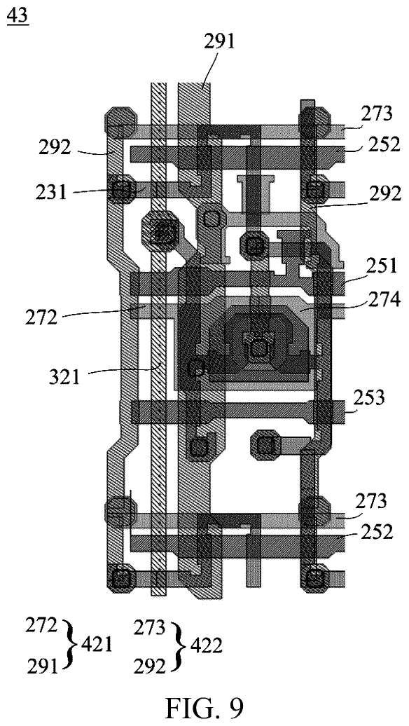

It should be noted that structures of various parts of a same wire in different pixel units or compensation units are different. For example, a structure of a part of the first scanning line 251 in the compensation unit 42 is different from a structure of a part of the first scanning line 251 in an invalid pixel 43. However, since the two parts are just different parts of the first scanning line. Therefore, the line will still be represented using a same reference numeral. For example, in the compensation unit 42 in FIG. 6, the first scanning line is represented using reference numeral 251, and in the invalid pixel 43 in FIG. 9, the first scanning line is also represented using reference numeral 251. Similarly, for other wires, a same wire will also be represented using a same reference numeral. In addition, in one or more embodiments of the present disclosure, wires of a same type will be represented using a same reference numeral. For example, in the compensation unit 42 in FIG. 6, a first data line is represented using reference numeral 321, and in the invalid pixel 43 in FIG. 9, a first data line is also represented using reference numeral 321. The reference numerals of the other wires may be given in a way similar to that for the first scanning line and the first data line. Details are not described herein again.

It should be noted that in one or more embodiments of the present disclosure, to explain a different design with respect to a conventional display device, a data line requiring winding will be defined as a second data line, a data line not requiring winding will be defined as a first data line. Different reference numerals are used for explanation. However, it should be noted that both the first data line and the second data line are configured to transmit data signals.

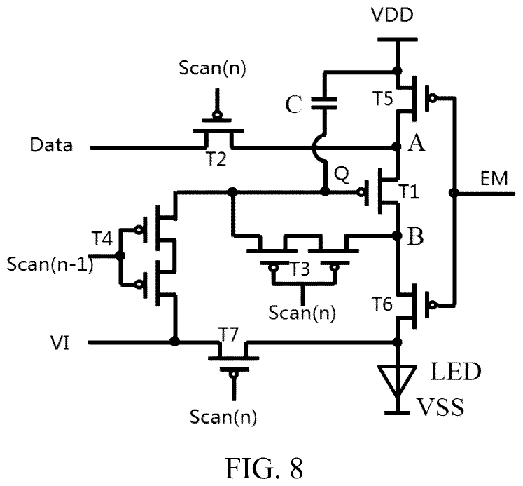

It should be noted that since in one or more embodiments of the present disclosure, a circuit design in one or more embodiments of the present disclosure are illustrated using a circuit diagram and a perspective view, a same wire will be illustrated using different reference numerals. For example, in FIG. 6, the first scanning line is represented using reference numeral 251, and in FIG. 8, the first scanning line is represented using reference numeral Scan(n).

Specifically, as shown in FIGS. 6 to 9, by using an n-th-stage gate drive circuit as an example, the first scanning line 251 is a scanning line of the n-th-stage gate drive circuit. In FIG. 8, the reference numeral of the scanning line is Scan(n).

Specifically, as shown in FIG. 6, FIG. 8, and FIG. 9, in FIG. 5, the projection of the first scanning line 251 on the substrate and the projection of the compensation wiring 271 on the substrate overlap with each other, and thus the first scanning line 251 and the compensation wiring 271 form a capacitor in the compensation unit. An impedance of the first scanning line is increased by the capacitor to compensate for the first scanning line 251. However, in FIG. 9, a first electrode plate of a storage capacitor C is formed by the first metal layer, and a second electrode plate 274 of a storage capacitor is formed by the second metal layer. The electrode plates of the two capacitors are different, and thus the structures of the two capacitors are different and have different functions. Moreover, it can be seen from FIG. 6 and FIG. 9 that the area of the part of the first scanning line 251 in the compensation unit is greater than the area of the part of the first scanning line 251 in the invalid pixel. Therefore, the capacitance value of the compensation unit can be adjusted to compensate for the first scanning line.

It should be noted that both FIG. 5 and FIG. 8 show the structures of some adjacent pixel units or compensation units. Therefore, there may be some repeated structures in FIG. 5 and FIG. 8. For example, in FIG. 5, there are two second scanning lines 252. Actually, the two second scanning lines 252 belong to the compensation unit and a compensation unit or pixel unit adjacent to the compensation unit, respectively. This will not be described again in the following embodiments.

It should be noted that FIG. 9 shows a structural design of an invalid pixel. However, it can be understood that a difference between a display pixel and an invalid pixel is that the invalid pixel does not have a light-emitting unit. The structural designs of other films (including the active layer to the second source drain layer) of a display pixel in the display region are same as the structural design of the invalid pixel. The following embodiments are described in detail by using a case that the structural designs of other films of the display pixel are same as the structural design of the invalid pixel as an example.

In one or more embodiments, the first scanning line extends from the display region to the transition region, and the parts of the scanning line on two sides of the opening region respectively are disconnected. The compensation unit includes a compensation capacitor, the compensation capacitor includes a first electrode plate and a second electrode plate. The first scanning line includes the first electrode plate of which the projection on the substrate overlaps with the projection of the compensation wiring on the substrate. The compensation wiring includes the second electrode plate of which the projection on the substrate overlaps with the projection of the first scanning line on the substrate. By extending the first scanning line upwards to form the first electrode plate and forming the compensation wiring as the second electrode plate, voltage drop of a first scanning line in a row where the opening region is located can be compensated for by the compensation capacitor, thereby preventing non-uniform display.

Specifically, in a case that the first scanning line extends from the display region to the transition region and is disconnected at the transition region, the first scanning line extends to two sides to form the first electrode plate of the compensation capacitor and the compensation wiring forms the second electrode plate of the compensation capacitor, such that the compensation capacitor is arranged in the invalid pixel region and the compensation unit can replace the invalid pixel, thereby preventing an increased area of the transition area of the display panel. Moreover, since the compensation unit is not arranged in the winding region, data lines of the winding region can be arranged on different metal layers for winding, thereby reducing the area of the winding region, further reducing the area of the transition region, and reducing the area of a black edge between the display region and the opening region.

Specifically, in a case that the first scanning line extends from a side of the display region to a side of the transition region and is wound from a side of the transition region to another side of the transition region, the first scanning line on a side can be disconnected, such that the first scanning line extends to two sides to form the first electrode plate of the compensation capacitor. The compensation wiring forms the second electrode plate of the compensation capacitor so that the compensation capacitor is arranged in the invalid pixel region, to compensate for the voltage drop of the first scanning line, thereby preventing non-uniform display.

Specifically, since there are missing pixels in a row where the opening region is located, no matter the first scanning line is disconnected at the transition region or the first scanning line is connected by winding at the transition region, due to the missing pixels, the capacitance of the first scanning line in a row where the opening region is located is less than the capacitance of the first scanning line in a row where a non-opening region is located, that is, the voltage drop of the first scanning line in a row where the opening region is located is less than the capacitance of the first scanning line in a row where the non-opening region is located. For the foregoing problem, in one or more embodiments of the present disclosure, the first scanning line is disconnected at the invalid pixel region, such that the first scanning line and the compensation wiring form the compensation capacitor to compensate for through the voltage drop of the first scanning line, thereby preventing non-uniform display.

In one or more embodiments, as shown in FIG. 6 and FIG. 7, the compensation unit 42 further includes a power supply high-potential signal line 421. At least part of the power supply high-potential signal line 421 is arranged on the second metal layer 27, and the power supply high-potential signal line 421 is connected to the compensation wiring 271. The power supply high-potential signal line is connected to the compensation wiring, so that when the compensation wiring and the first scanning line form the capacitor, the two electrode plates of the capacitor are respectively connected to the power supply high-potential signal line and the first scanning line. The first scanning line needs to charge the capacitor to increase the impedance of the first scanning line, such that the impedance of the scanning line in a row where the opening region is located is close or even identical to the impedances of scanning lines in other rows, thereby preventing the problem of non-uniform display.

In one or more embodiments, as shown in FIGS. 5 to 7, the source drain layer 35 includes a first source drain layer 29 and a second source drain layer 32. The display panel 2 further includes a first planarization layer 31. The second source drain layer 32 is arranged on a side of the first source drain layer 29 away from the second metal layer 27. The first planarization layer 31 is arranged between the first source drain layer 29 and the second source drain layer 32. The power supply high-potential signal line 421 includes a first power supply high-potential signal line 272 on the second metal layer 27 and a second power supply high-potential signal line 291 on the first source drain layer 29; the first power supply high-potential signal line 272 is connected to the compensation wiring 271. The second power supply high-potential signal line 291 passes through a via hole of the first planarization layer 31 and is then connected to the compensation wiring 271. The first power supply high-potential signal line is directly connected to the compensation wiring, and the second power supply high-potential signal line is connected to the compensation wiring through the via hole, such that the compensation wiring, the first power supply high-potential signal line, and the second power supply high-potential signal line have the same potential. The compensation wiring is maintained at the potential of a voltage signal output by the power supply high-potential signal line to compensate for the first scanning line. Moreover, the way of arranging the first power supply high-potential signal line and the second power supply high-potential signal line is same as that of arranging the invalid pixel and a normally displayed pixel unit, so as to prevent defective display caused by manufacturing process differences.

Specifically, (d) in FIG. 7 shows the positions of multiple via holes 431, but does not limit that the via holes are located in one layer. The via holes 431 may be via holes in the first planarization layer or via holes in an interlayer insulating layer.

It should be noted that although the first power supply high-potential signal line and the compensation wiring are illustrated using different reference numerals, it can be seen from FIG. 6 and FIG. 7 that in actual design, the first power supply high-potential signal line 272 and the compensation wiring 271 are different parts of a same wire.

Specifically, as shown in FIGS. 6 to 9, it can be seen that the way of arranging the power supply high-potential signal line 421 in the compensation unit 42 is same as that of arranging the power supply high-potential signal line 421 in the invalid pixel 43, such that during forming the power supply high-potential signal line, no defective display will be caused due to the difference between manufacturing processes of the compensation unit and another pixel unit, thereby improving the display effect of the display panel.

In one or more embodiments, as shown in FIGS. 5 to 7, the display panel 2 further includes an interlayer insulating layer 28. The interlayer insulating layer 28 is arranged between the first source drain layer 29 and the second metal layer 27. The compensation unit 42 further includes:
a second scanning line 252 on the first metal layer 25 and insulated from the first scanning line 251;
an initialization signal line 422 including a first initialization signal line 273 and a second initialization signal line 292, the first initialization signal line 273 being on the second metal layer 27, the second initialization signal line 292 being on the first source drain layer 29, and the second initialization signal line 292 passing through a via hole in the interlayer insulating layer 28 and being connected to the first initialization signal line 273;
a light-emitting control signal line 253 on the first metal layer 25; and
a first data line 321 on the second source drain layer 32.

Specifically, in one or more embodiments of the present disclosure, by designing the second scanning line, the initialization signal line, the light-emitting control signal line, and the first data line in the compensation unit, the compensation unit has the same film layer arrangement as the invalid pixel and the display pixel, thereby preventing a problem of defective display caused by the difference between manufacturing processes of the compensation unit and other pixel units.

Specifically, it can be seen from FIG. 6, FIG. 8, and FIG. 9 that the first scanning line 251 and the second scanning line 252 are arranged in the pixel drive circuit to respectively control transistors. In one or more embodiments of the present disclosure, by arranging the second scanning line 252 in the compensation unit and making the manufacturing process of the scanning line of the compensation unit be same as the manufacturing process of a scanning line of another pixel unit, defective display caused by differences in film layer thickness and manufacturing process is prevented.

Specifically, it can be seen from FIG. 6, FIG. 8, and FIG. 9 that the pixel drive circuit includes the initialization signal line, the light-emitting control signal line, and the first data line. In one or more embodiments of the present disclosure, by arranging the initialization signal line 422, the light-emitting control signal line 253, and the first data line 321 in the compensation unit and making the manufacturing processes of the initialization signal line, the light-emitting control signal line, and the first data line of the compensation unit be same as the manufacturing processes of an initialization signal line, a light-emitting control signal line, and a first data line in another pixel unit, defective display caused by difference in film layer thickness and manufacturing processes is prevented.

In one or more embodiments, as shown in FIG. 5, the display panel 2 further includes a second data line 322 arranged in the winding region 414. The second data line 322 includes a first part 322a arranged on the second source drain layer 32 and a second part 322b arranged on the first source drain layer 29. The first part passes through a via hole in the first planarization layer 31 and is then connected to the second part 322b. By arranging the second data line on the first source drain layer and the second source drain layer, during winding the second data line, the second data line can be wound from the first source drain layer and the second source drain layer. Accordingly, the width required for winding can be reduced, such that the area of the winding region can be reduced and a black edge between the display region and the opening region is reduced.

Specifically, in FIG. 5, the first part 322a is not connected to the second part 322b. However, in actual design, for the second data wire which needs to be transferred to the first source drain layer for winding, the first part 322a may be connected to the second part 322b; for the second data line which is directly wound in the second source drain layer, the second data line does not need to be transferred to the first source drain layer and may be directly wound on the second source drain layer. Therefore, although in FIG. 5, the first part 322a is not directly connected to the second part 322b, the first part and the second part may be connected or not connected depending on actual design of the second data line. Similarly, for design of a third part and a fourth part, refer to the design of the first part and the second part. Details are not described here again.

Specifically, in the conventional display device, since the compensation unit is arranged in the winding region, the compensation unit will occupy the first source drain layer and the second metal layer, the scanning line needs to be wound in the winding region, and then the data line has to be wound on the second source drain layer. Thus, the winding region needs to provide space for both the compensation unit and the data line, resulting in a large width of the winding region. However, in the present disclosure, the compensation unit is arranged in the invalid pixel region, such that the width of the winding region is reduced, and further, the second data line may be wound on the first source drain layer and the second source drain layer, thereby further reducing the width of the second data line requiring winding, further reducing the width of the winding region, and thus reducing the black edge between the display region and the opening region.

In one or more embodiments, as shown in FIG. 5, the display panel 2 further includes a first gate insulating layer 24, a second gate insulating layer 26, and the interlayer insulating layer 28. The first gate insulating layer 24 is arranged between the first metal layer 25 and the substrate 21. The second gate insulating layer 26 is arranged between the first metal layer 25 and the second metal layer 27. The interlayer insulating layer 28 is arranged between the second metal layer 27 and the first source drain layer 29. The second data line 322 further includes a third part 322c and a fourth part 322d. The third part 322c is arranged on the second metal layer 27. The fourth part 322d is arranged on the first metal layer 25. The second part 322b passes through a via hole of the interlayer insulating layer 28 and is then connected to the third part 322c. The third part 322c passes through a via hole of the second gate insulating layer 26 and is then connected to the fourth part 322d. By arranging the second data line on the first source drain layer, the second source drain layer, the first metal layer, and the second metal layer, during winding the second data line, the second data line may be wound from the first source drain layer, the second source drain layer, the first metal layer, and the second metal layer. Accordingly, the width required for winding can be reduced, such that the area of the winding region can be reduced and a black edge between the display region and the opening region is reduced.

Specifically, the foregoing embodiments are described in detail by using the case that the second data line is arranged on the first source drain layer and the second source drain layer or the case that the second data line is arranged on the first source drain layer, the second source drain layer, the first metal layer, and the second metal layer as an example. However, one or more embodiments of the present disclosure is not limited thereto. For example, the second data line may be arranged on the first source drain layer, the second source drain layer, and the first metal layer.

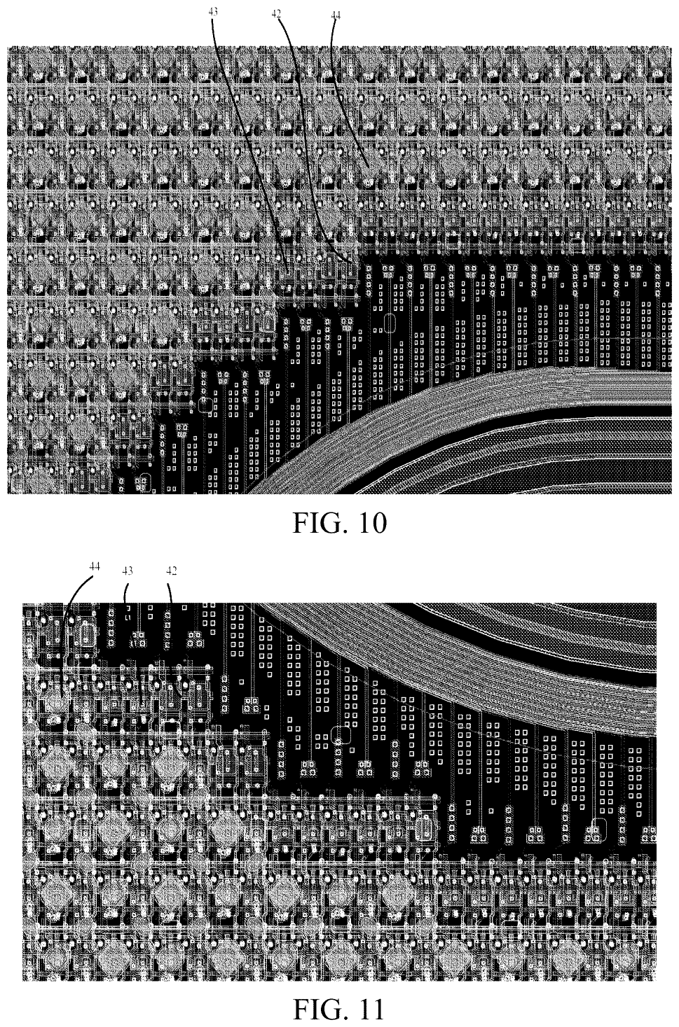

In one or more embodiments, as shown in FIG. 5, FIG. 10, and FIG. 11, the display region 411 is provided with display pixels 44, the invalid pixel region 413 is provided with invalid pixels 43, and the invalid pixels 43 are arranged between the display pixels 44 and the compensation units 42. By arranging the invalid pixels between the compensation units and the display pixels, a transition to the display pixels can be achieved by the invalid pixels, thereby preventing defective display caused by inconsistency in electrical signals, film layer thicknesses, etc. between the display region and the non-display region. In addition, the compensation units are arranged on a side of the invalid pixels close to the opening region, so that in a case that the compensation units are configured for compensation, the compensation units will not affect the transition effect of the invalid pixels, allowing for normal display of the display panel.

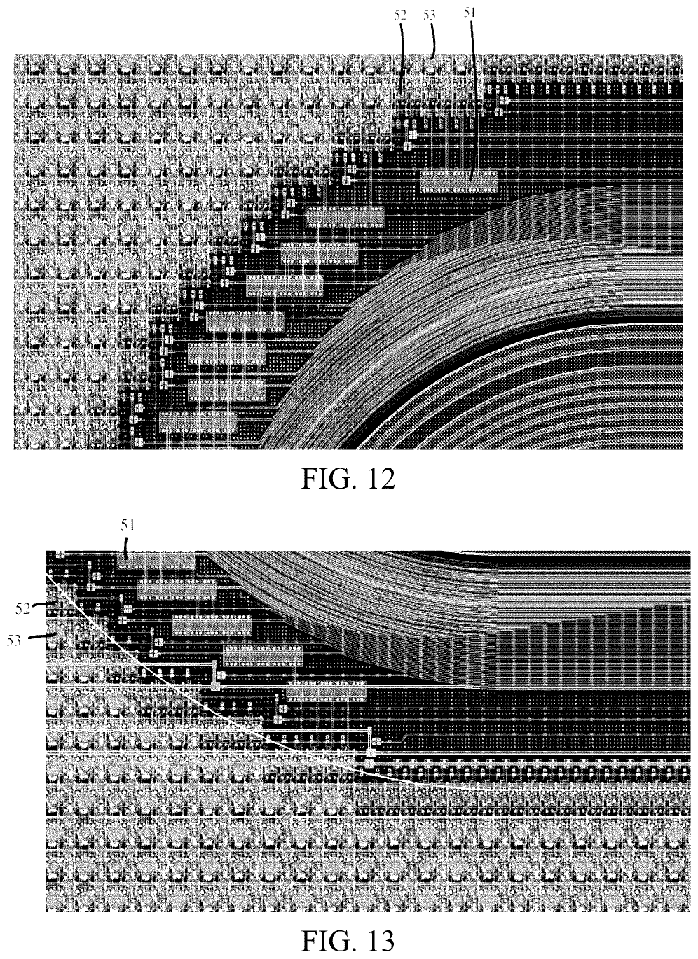

Specifically, as shown in FIGS. 10 to 13, FIG. 10 shows a perspective view of an upper left side of an opening region of a display panel according to one or more embodiments of the present disclosure; FIG. 11 shows a perspective view of a lower left side of an opening region of a display panel according to one or more embodiments of the present disclosure; FIG. 12 shows a perspective view of an upper left side of an opening region of a conventional display device; and FIG. 13 shows a perspective view of a lower left side of an opening region of a conventional display device. It can be seen from FIGS. 11 to 13 that in the conventional display device, invalid pixel units 52 are arranged adjacent to normal display pixel units 53. Compensation units 51 of the conventional display device are arranged in the winding region, and then the compensation units 51 need to occupy the space of the winding region, resulting in a large width of the winding region. Moreover, it can be seen from the perspective views of the display panel according to one or more embodiments of the present disclosure that the compensation units 42 according to one or more embodiments of the present disclosure are arranged in the invalid pixel region and are arranged adjacent to the invalid pixels 43, such that the width of the winding region can be reduced. Moreover, the compensation units 42 can replace the invalid pixels 43, without increasing the width of the invalid pixel region, thereby reducing a black edge between the display region and the opening region.

Specifically, during arrangement of the compensation unit, the number of the compensation units may be set depending on different compensation effects. Compensation curves shown in FIG. 17 are used as an example. A scanning line in a row other than the last row has basically consistent compensation capacitance. Therefore, the capacitance values and the number of the compensation capacitors for the scanning lines in different rows may be made consistent. For example, 4 columns of compensation units are provided for each of the scanning lines in the 40th row to the 79th row, and 2 columns of compensation units are provided for the scanning line in the 80th row, such that the voltage drops of the scanning lines in different rows are consistent and display uniformity is improved. Moreover, the compensation units in a row of scanning line may be arranged on two sides of the opening region, respectively. For example, for the 40th row of scanning line, 2 columns of compensation units are arranged on the left side of the opening region, and 2 columns of compensation units are arranged on the right side of the opening region.

In the foregoing embodiments, the number of columns of compensation units for each row of scanning line is illustrated using the compensation curves shown in FIG. 17 as an example. However, one or more embodiments of the present disclosure is not limited thereto. For example, in a case that a compensation curve changes, the arrangement position of the compensation units, the capacitance values of the compensation units for each row, or the number of the compensation units may be adjusted based on the principle shown in one or more embodiments of the present disclosure, to make the voltage drops of scanning lines in different rows consistent. For example, the number of columns of compensation units for each row of scanning line ranges from 2 to 4.

Specifically, a resolution of 2712*1220 of a display panel is used as an example, that is, the display panel includes 1220 columns of pixels. Pixel design (blue sub-pixels and red sub-pixels are in a same column, and each column of sub-pixels includes two columns of sub-pixels) shown in FIG. 11 is used as a pixel design example. That is, the display panel includes 2440 columns of sub-pixels. Correspondingly, in the conventional display panel, invalid sub-pixels may be arranged at a part of the 1161th to 1281th columns of sub-pixels close to the opening region. In one or more embodiments of the present disclosure, invalid sub-pixels in the 1161th to 1281th columns of sub-pixels are replaced with compensation units and invalid sub-pixels in the 1259th to 1281th columns of sub-pixels are replaced with compensation units, thereby preventing an increased area of the transition region of the display panel. Moreover, since the compensation units are not arranged in the winding region, the data line in the winding region may be arranged on different metal layers for winding, thereby reducing the area of the winding region, further reducing the area of the transition region, and reducing a black edge between the display region and the opening region.

Specifically, arranging the compensation units in the 1161th to 1183th columns of sub-pixels does not specifically refers to that each row includes compensation units located in the 1161th to 1183th columns of sub-pixels, but refers to that compensation units in different rows are arranged in the 1161th to 1183th columns of sub-pixels. For example, in a direction from an upper left to a lower right of the opening region, the compensation units in a topmost row are arranged in the 1182th and 1183th columns of sub-pixels, and the compensation units in a next row of the topmost row are arranged in the 1180th and 1181th columns of sub-pixels. Correspondingly, the compensation units in different rows are arranged in the 1161th to 1183th columns of sub-pixels.

Specifically, in one or more embodiments of the present disclosure, the arrangement position of the compensation units is described in detail using a resolution of 2712*1220 of the display panel as an example and using the pixel design shown in FIG. 11 as a pixel design example. However, one or more embodiments of the present disclosure is not limited thereto. For example, when the resolution of the display panel is another resolution and/or the pixel design is another pixel design, a person skilled in the art may adjust the arrangement position of the compensation units, the capacitance values of the compensation units for each row, and the number of the compensation units based on the principle shown in one or more embodiments, to make the voltage drops of scanning lines in different rows consistent.

In one or more embodiments, various wires in the compensation unit are correspondingly connected to various wires in the invalid pixel. By correspondingly connecting the wires in the compensation unit and the wires in the invalid pixel, during arrangement of the compensation unit, the compensation unit can replace the invalid pixel, and the compensation unit can achieve a transition to the display pixel.

Specifically, for example, the part of the first scanning line in the compensation unit is connected to the part of the first scanning line in the invalid pixel. Only the width of the first scanning line needs to be changed, and the position of the first scanning line may be set according to the arrangement position of the invalid pixel, so that the compensation unit can replace the original part of the invalid pixel to transmit a signal of the first scanning line, without occupying extra space.

Similarly, the power supply high-potential signal line, the first data line, the second scanning line, the initialization signal line, and the light-emitting control signal line in the compensation unit may also be designed based on the design of the first scanning line. For example, the first data line may be designed based on the design mode of the invalid pixel, without changing the first data line, thereby maintaining a unified manufacturing process and preventing manufacturing process differences affecting display. Moreover, in a case that the compensation unit is used to replace the invalid pixel, defective display caused by an excessive difference between the structure of the compensation unit and the structure of the invalid pixel is prevented.

In one or more embodiments, as shown in FIGS. 5 to 9, the display panel further includes an active layer 23. The active layer 23 includes an active pattern 231. The projection area of the active pattern 231 in the invalid pixel 43 on the substrate 21 is greater than the projection area of the active pattern 231 in the compensation unit 42 on the substrate 21. The projection area of the active pattern in the compensation unit on the substrate is less than the projection area of the active pattern in the invalid pixel on the substrate, such that the number of transistors in the compensation unit is reduced and there are fewer signals in the compensation unit, thereby preventing the effect of other signals on the scanning line, preventing defective display caused by an unstable signal in the compensation unit, and improving the stability of the display panel.

Specifically, as shown in FIG. 6 and FIG. 7, it can be seen that the active pattern in the compensation unit is only arranged on a region corresponding to the light-emitting control signal line 253, such that a drive transistor and part of a switching transistor are not formed in the compensation unit, thereby preventing the effect of the compensation unit on the pixel drive circuit and improving the stability of the display panel.

In one or more embodiments, as shown in FIG. 4, the display region 411 is arranged around the opening region 418, and the shape of the opening region 418 is at least one of a track shape, a circular shape, or a square shape.

Specifically, one or more embodiments of the present disclosure is not limited to the shape of the opening region being one of the track shape, the circuit shape, or the square hole. For example, the opening region may be arranged at the upper part of the display panel, so that the opening region is in contact with a bezel, in which case the opening region may be semicircular or arc-shaped.

In one or more embodiments, along an arrangement direction of the first scanning line, the compensation units are arranged on two sides of the opening region respectively. The compensation units are arranged on two sides of the opening region, so that the display panel has good symmetry properties, and thus during display, a problem of defective display caused by manufacturing process differences and uniformity differences in asymmetric designs is prevented.

In one or more embodiments, the display panel includes a longitudinal axis of symmetry from an upper bezel to a lower bezel. The opening region is arranged symmetrically about the longitudinal axis of symmetry of the display panel. Along an arrangement direction of the first scanning line, the capacitance of the compensation units on the left side of the opening region is equal to the capacitance of the compensation units on the right side of the opening region. In a case that the opening region is arranged symmetrically about the longitudinal axis of symmetry of the display panel, the voltage drops of the scanning lines on two sides of the opening region are consistent. Therefore, the compensation units respectively on two sides of the opening region have the equal capacitance. Therefore, the voltage drops of the scanning lines on two sides are consistent and display uniformity is improved.

Specifically, by making the number of compensation units respectively on two sides of the opening region be equal and the capacitance values of the compensation units on two sides of the opening region be equal, the compensation units respectively on two sides of the opening region have the equal capacitance, such that the voltage drops of the scanning lines on two sides of the opening region are consistent and display uniformity is improved.

Specifically, further, by making the number of compensation units respectively on two sides of the opening region be unequal, the capacitance values of the compensation units respectively on two sides of the opening region be unequal, but the total capacitance values of the compensation units respectively on two sides of the opening region be equal, the voltage drops of the scanning lines on two sides of the opening region are consistent and display uniformity is improved.

Specifically, further, the compensation units arranged on the left side of the opening region and the compensation units arranged on the right side of the opening region are symmetric about the longitudinal axis of symmetry of the display panel. By making the compensation units respectively on two sides of the opening region be arranged symmetrically about the longitudinal axis of symmetry of the display panel, the voltage drops of the scanning lines on two sides of the opening region are consistent. Moreover, during formation of the display panel, defective display caused by inconsistent manufacturing processes is prevented.

In one or more embodiments, the display panel includes a longitudinal axis of symmetry from an upper bezel to a lower bezel. A longitudinal axis of symmetry of the opening region is arranged on a side of the longitudinal axis of symmetry of the display panel. Along an arrangement direction of the first scanning line, the capacitance of the compensation units arranged on a side of the longitudinal axis of symmetry of the opening region away from the longitudinal axis of symmetry of the display panel is greater than the capacitance of the compensation units arranged on a side of the longitudinal axis of symmetry of the display panel away from the longitudinal axis of symmetry of the opening region. For a case that the opening region is arranged towards a side of the display panel, the distances from the scanning line respectively on two sides of the opening region to the hole are different. Therefore, the capacitance of the compensation units on a side closer to the hole can be enabled to be greater than the capacitance of the compensation units on a side farther from the hole, so that the voltage drops of the scanning lines respectively on two sides of the opening region are consistent and non-uniform display is prevented.

Specifically, the case that the opening region is arranged towards the left side of the display panel is used as an example for explanation. The display panel includes a longitudinal axis of symmetry from an upper bezel to a lower bezel. A longitudinal axis of symmetry of the opening region is arranged on the left side of the longitudinal axis of symmetry of the display panel. Along an arrangement direction of the first scanning line, the capacitance of the compensation units arranged on the left side of the opening region is greater to the capacitance of the compensation units arranged on the right side of the opening region. For a case that the opening region is arranged towards the left side of the display panel, the impedance of the scanning line on the left side of the opening region is less than the impedance of the scanning line on the right side of the opening region, resulting in a problem of non-uniform display. In one or more embodiments of the present disclosure, the capacitance of the compensation units on the left side of the opening region is greater than the capacitance of the compensation units on the right side of the opening region, so that the voltage drops of the scanning lines on two sides of the opening region are consistent and non-uniform display is prevented.

Specifically, in a case that the capacitance of the compensation units on the left side of the opening region is greater than the capacitance of the compensation units on the right side of the opening region, the design may be implemented by adjusting the capacitance value of each compensation unit in the compensation units respectively on two sides and the number of the compensation units. For example, the number of the compensation units on the left side of the opening region is equal to the number of capacitors of the compensation units on the right side of the opening region, but the capacitance value of each compensation unit on the left side of the opening region is greater than the capacitance value of each compensation unit on the right side of the opening region.

Specifically, when adjusting the capacitance value of each compensation unit, the area of the capacitor electrode plate of the compensation unit may be adjusted. For example, the area of the capacitor electrode plate of the compensation unit on the left side of the opening region is greater than the area of the capacitor electrode plate of the compensation unit on the right side of the opening region, such that the capacitance value of each compensation unit on the left side of the opening region is greater than the capacitance value of each compensation unit on the right side of the opening region.

Specifically, further, the number of the compensation units on the left side of the opening region is greater than the number of capacitors of the compensation units on the right side of the opening region, and the capacitance value of each compensation unit on the left side of the opening region is equal to the capacitance value of each compensation unit on the right side of the opening region, such that the capacitance of the compensation units on the left side of the opening region is greater and the capacitance of the compensation units on the right side of the opening region.

Specifically, the foregoing embodiments are described in detail using the case that the opening region is arranged towards the left side of the display panel as an example. However, one or more embodiments of the present disclosure is not limited thereto. For example, in a case that the opening region is arranged towards the right side of the display panel, the capacitance of the compensation units on the right side of the opening region is greater than the capacitance of the compensation units on the left side of the opening region, so that the voltage drops of the scanning lines respectively on two sides of the opening region are consistent and non-uniform display is prevented.

The foregoing embodiments are described in detail using the case that the compensation units are arranged on two sides of the opening region as an example. However, one or more embodiments of the present disclosure is not limited thereto. For example, the compensation units may be arranged only on one side of the opening region.

In one or more embodiments, the display panel includes multiple rows of first scanning lines. In the transition region, the overlapping areas between the projections of the first scanning lines of different rows on the substrate and the projections of the compensation wirings on the substrate are different. The overlapping areas between the projections of the first scanning lines of different rows on the substrate and the projections of the compensation wirings on the substrate are different, then capacitance compensation of different amplitudes is performed on different first scanning lines, and thus the impedances of the first scanning lines of different rows are consistent.

Specifically, for example, the opening region is a circular hole, the positions where the first scanning lines of different rows start winding are different, and the impedances of the first scanning lines of different rows are different. Therefore, by making the capacitance values of the compensation units for different rows to be different, the impedances of the first scanning lines having different impedances can tend to be consistent or can be consistent, thereby preventing non-uniform display.

In one or more embodiments, the first scanning lines in different rows on the same side of the opening region have different lengths, and along the direction in which the lengths of the first scanning lines increase, the capacitance of the compensation units gradually decreases. In a case that the first scanning lines in different rows on the same side of the opening region have different lengths, as the lengths of the first scanning lines increase, the capacitance of the compensation units may be decreased, so that the voltage drops of the first scanning lines in different rows are consistent and the display uniformity of the display panel is improved.

Specifically, the case that the lengths of the first scanning lines in different rows on the same side of the opening region increase along a direction from a middle region of the opening region to the upper side of the opening region is used as an example for explanation. Along the direction form the middle region of the opening region to the upper side of the opening region, the lengths of the scanning lines in different rows on the same side of the opening region gradually increase, and the capacitance of the compensation units gradually decreases. Along the direction in which the lengths of the first scanning lines gradually increase, the capacitance of the compensation units is decreased, so that the voltage drops of the first scanning lines in different rows are consistent and the display uniformity of the display panel is improved.

Specifically, in a case that the capacitance of the compensation units gradually decreases in a direction from the middle region of the opening region to the upper side of the opening region, the design may be implemented by adjusting the capacitance value of each compensation unit in the compensation units in each row and the number of the compensation units. For example, the number of the compensation units is kept unchanged along the direction from the middle region of the opening region to the upper side of the opening region, but the capacitance value of the compensation unit gradually decreases along the direction from the middle region of the opening region to the upper side of the opening region.

Specifically, in a case of adjusting the capacitance value of each compensation unit, the area of the capacitor electrode plate of the compensation unit may be adjusted. For example, along the direction from the middle region of the opening region to the upper side of the opening region, the capacitance of the compensation unit gradually decreases.

Specifically, the number of the compensation units gradually decreases along the direction from the middle region of the opening region to the upper side of the opening region, but the capacitance values of the compensation units are different along the direction from the middle region of the opening region to the upper side of the opening region, so that the capacitance of the compensation units gradually decreases along the direction from the middle region of the opening region to the upper side of the opening region.

The foregoing embodiments are described in detail using the case that the capacitance of the compensation units gradually decreases along the direction from the middle region of the opening region to the upper side of the opening region as an example. However, one or more embodiments of the present disclosure is not limited thereto. For example, along a direction form the middle region of the opening region to the lower side of the opening region, the capacitance of the compensation units may also gradually decrease, so that the impedances of scanning lines on the same side of the opening region are consistent and display uniformity of the display panel is improved.

The foregoing embodiments are described in detail using the case that the capacitance of compensation units for the first scanning lines in different rows is not equal as an example. However, one or more embodiments of the present disclosure is not limited thereto. For example, the capacitance of the compensation units of the first scanning lines in different rows may be equal.

In one or more embodiments, the display panel includes multiple rows of first scanning lines. In the transition region, the number of compensation units corresponding to first scanning lines of different rows are different.

Specifically, the number of compensation units for different rows of first scanning lines are different, then capacitance compensation of different amplitudes is performed on the first scanning lines in different rows, and thus the impedances of the first scanning lines of different rows are consistent. For example, the first scanning line in one row is provided with two compensation units, the first scanning line in another row is provided with one compensation unit, and each compensation unit has the same capacitance. Therefore, capacitance compensation of different magnitudes may be performed on the first scanning lines in different rows. Moreover, the number of compensation units for different rows of first scanning lines being different does not define that the capacitance sums of the compensation units for different rows of first scanning liens are different.

The foregoing embodiments are described in detail using the case that the number of compensation units for different rows of first scanning lines are different as an example. However, embodiments of the present disclosure are not limited thereto. For example, the numbers of compensation units for different rows of first scanning lines are equal.

In one or more embodiments, as shown in FIG. 8, the display panel further includes multiple light-emitting devices LEDs arranged in an array and a pixel drive circuit for driving the light-emitting devices LEDs. The pixel drive circuit includes T1˜T7.

A first initialization transistor T4 is connected to an initialization signal line VI and configured to input an initialization signal to a first node Q under the control of a second scanning line.

A switching transistor T2 is configured to input a data signal to a second node A under the control of a first scanning signal.

A drive transistor T1 is configured to drive the light-emitting device LED to emit light under the control of the first node Q and the second node A.

A compensation transistor T3 is connected to the drive transistor T1 by the first node Q and a third node B and configured to compensate for a threshold voltage of the drive transistor T1 under the control of the first scanning line.

A second initialization transistor T7 is connected to the initialization signal line VI and configured to input an initialization signal to an anode of the light emitting device LED under the control of the first scanning line.

A first light-emitting control transistor T5 is connected to the drive transistor T1 by the second node A and configured to conduct current from the power supply high-potential signal line VDD to the drive transistor T1 under the control of a light-emitting control signal.

A second light-emitting control transistor T6 is connected to the drive transistor T1 by the third node B and configured to conduct current from the drive transistor T1 to the anode of the light-emitting device LED under the control of the light-emitting control signal.

In one or more embodiments, as shown in FIG. 8, the pixel drive circuit further includes a storage capacitor C. A terminal of the storage capacitor C is connected to the power supply high-potential signal line VDD, and another terminal of the storage capacitor C is connected to the first node Q.

It can be understood that in one or more embodiments of the present disclosure, as shown in FIG. 8, a data line Data transmits a data signal, the initialization signal line VI transmits the initialization signal, the first scanning line Scan(n) transmits the first scanning signal, the second scanning line Scan(n−1) transmits a second scanning signal, a light-emitting control signal line EM transmits the light-emitting control signal, and a power supply low-potential signal line VSS transmits a low potential.

It should be noted that Scan(n−1) and Scan(n) represent scanning lines of two stages. In addition, it can be understood that the pixel drive circuit in one or more embodiments of the present disclosure is controlled by the scanning lines of the current stage and the scanning lines of the previous stage. Therefore, in the pixel drive circuit of the current stage, the first scanning line refers to Scan(n) and the second scanning line refers to Scan(n−1); and in the pixel drive circuit of the previous stage, the first scanning line refers to Scan(n−1) and the second scanning line refers to Scan(n−2). Scanning lines of other stages may be determined with reference to the above description. Details are not described here again.

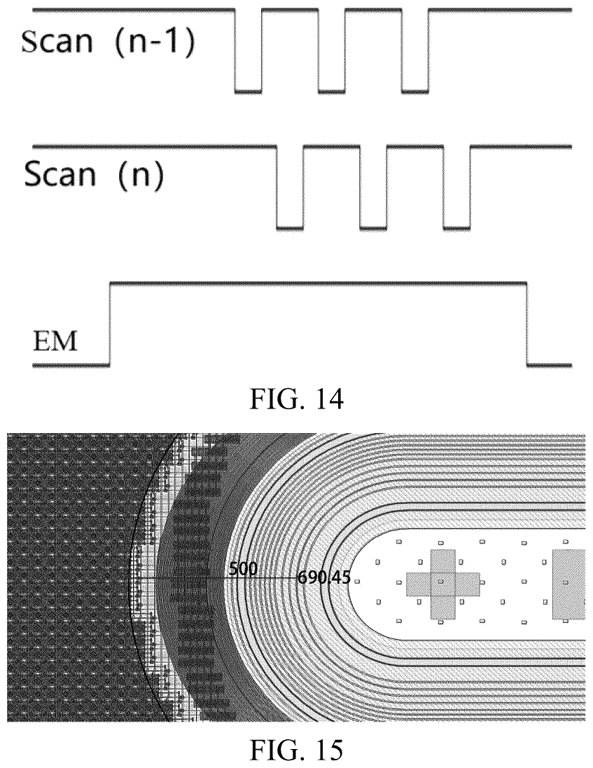

As shown in FIG. 14, FIG. 14 shows a timing diagram of signals of a pixel drive circuit according to one or more embodiments of the present disclosure. The pixel drive circuit may be controlled by different signals of the first scanning line Scan(n), the second scanning line Scan(n−1), and the light-emitting control signal line EM in different time periods.

It should be noted that in one or more embodiments of the present disclosure, one type of pixel drive circuit is described in detail. However, embodiments of the present disclosure are not limited thereto. For example, the pixel drive circuit may use multiple initialization signal lines, and separate control is implemented by scanning lines. This is not limited in one or more embodiments of the present disclosure.

In one or more embodiments, as shown in FIG. 5, the substrate 21 includes a first flexible layer 211, a blocking layer 212, and a second flexible layer 213.

In one or more embodiments, as shown in FIG. 5, the display panel 2 further includes a buffer layer 22, a second planarization layer 33, a pixel definition layer 34, and an organic layer 36.

In one or more embodiments, the display panel further includes a light-emitting functional layer. The light-emitting functional layer includes a pixel electrode layer, a light-emitting material layer, and a common electrode layer.

In one or more embodiments, the display panel may further be a liquid crystal display panel.

In one or more embodiments, as shown in FIG. 5, the transition region 412 further includes a first encapsulation region 415, a barrier region 416, and a second encapsulation region 417. By forming an undercut structure in the first encapsulation region 415 and the second encapsulation region 417 and arranging a barrier in the barrier region 416, during forming an encapsulation layer subsequently, the encapsulation layer may be broken in the first encapsulation region, the barrier region, and the second encapsulation region, thereby improving the encapsulation effect.

Specifically, the display panel in FIG. 5 is used as an example, and the width of the display panel in one or more embodiments of the present disclosure is compared with the width of the conventional display panel. The opening region of the conventional display device and the opening region of the display panel in one or more embodiments of the present disclosure each have a length of 2400 microns and a width of 1800 microns. As shown in FIG. 5, the width k of the first encapsulation region is 210 microns, the distance D between the undercut structure closest to the opening region and the opening region is 88 microns, the distance C between adjacent undercut structures is 15 microns, the width B of each undercut structure is 5 microns, the distance A between the undercut structure closest to the barrier region and the barrier region is 17 microns, 6 undercut structures are provided, the width j of the barrier region 416 is 36.4 microns, the distance d between the left side of the undercut structure of the first encapsulation region and the barrier region is 17.2 microns, the width f of the undercut structure of the first encapsulation region is 5 microns, the distance h between the right side of the undercut structure of the first encapsulation region and the winding region is 15 microns, the width u of the winding region is 169.4 microns, the width w of the invalid pixel region is 57 microns, and thus the width of the transition region is 510 microns.

Specifically, in the conventional display device, in a case that the widths of the first encapsulation layer, the barrier layer, the second encapsulation layer, and the invalid pixel region are not changed, the width of the winding region is 349.4 micron. In this case, the width of the transition region is 690 microns. That is, the width of the transition region of the display panel in one or more embodiments of the present disclosure is less than the width of the transition region of the convention display device.

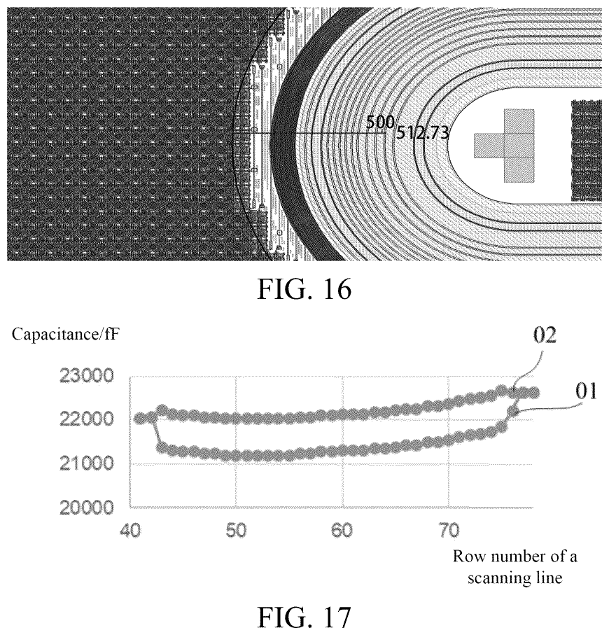

As shown in FIG. 15 and FIG. 16, FIG. 15 shows a perspective view of an actual product of a conventional display device, and FIG. 16 shows a perspective view of an actual product of a display panel according to one or more embodiments of the present disclosure. It can be seen from FIG. 15 and FIG. 16 that the width of the transition region of the conventional display device is 690.45 microns. However, the width of the transition region of the display panel according to one or more embodiments of the present disclosure is 512.73 microns. The width of the transition region of the display panel in one or more embodiments of the present disclosure is reduced with respect to the width of the transition region of the conventional display device, thereby reducing the black edge between the display region and the opening region.

As shown in FIG. 17, the abscissa represents a row number of a scanning line, and the ordinate represents the capacitance of the scanning line and the unit is fF. Curve 01 represents capacitance change of the scanning lines in the conventional display device when a scanning line in a row where the opening region is located is not compensated for. Curve 02 represents capacitance change of a scanning line in the display panel in one or more embodiments of the present disclosure when a scanning line in a row where the opening region is located is compensated for. It can be seen that there is a capacitance jump in curve 01, resulting in non-uniform display during display. But in one or more embodiments of the present disclosure, by arranging the compensation units, a capacitance jump can be prevented, thereby improving the display effect.

In addition, a display apparatus one or more embodiments of the present disclosure includes the display panel described in any one of the foregoing embodiments and an electronic component.

In one or more embodiments, the electrode component includes an under screen camera.

Following can be learned from the foregoing embodiments.

One or more embodiments of the present disclosure are directed to a display panel and a display apparatus. The display panel includes a display region, an opening region, and a transition region between the display region and the opening region. The display panel includes a substrate, a first metal layer, a second metal layer and a source drain layer. The first metal layer is on a side of the substrate. The first metal layer including one or more first scanning lines. The second metal layer is on a side of the first metal layer away from the substrate. The source drain layer is on a side of the second metal layer away from the first metal layer. The transition region includes an invalid pixel region and a winding region. The winding region is between the invalid pixel region and the opening region. The invalid pixel region is provided with a compensation unit. The compensation unit at least includes a compensation wiring on the second metal layer. A projection of the compensation wiring on the substrate overlaps with a projection of at least one of the one or more first scanning lines on the substrate. In the present disclosure, by arranging the compensation unit in the invalid pixel region, the compensation unit can replace the invalid pixel, thereby preventing an increased area of the transition region of the display panel. Moreover, since the compensation units are not arranged in the winding region, data lines in the winding region may be arranged on different metal layers for winding, thereby reducing the area of the winding region, further reducing the area of the transition region, and reducing the area of a black edge between the display region and the opening region. In addition, since the compensation unit includes the compensation wiring arranged on the second metal layer, and the projection of the compensation wiring on the substrate overlaps with the projection of the first scanning line on the substrate, the voltage drop of a first scanning line in a row where the opening region is located can be compensated for, thereby preventing non-uniform display.

In the foregoing embodiments, description of embodiments all have their own focuses, and for portions that are not described in detail in a particular embodiment, reference may be made to the related description in other embodiments.

In the foregoing embodiments, the display panel and the display apparatus according to embodiments of the present disclosure are introduced in detail. Specific examples are used herein to explain principles and implementations of the present disclosure. The descriptions of the foregoing embodiments are only used to help understand the technical solutions of the present disclosure and the core idea of the present disclosure. A person of ordinary skill in the art should understand that modifications may still be made to the technical solutions described in the foregoing embodiments or equivalent replacements may be made to some technical features thereof. Such modifications and replacements do not cause the essence of the corresponding technical solutions to depart from the scope of the technical solutions of embodiments of the present disclosure.

What is claimed is:

1. A display panel, comprising a display region, an opening region, and a transition region between the display region and the opening region, the display panel comprising:
a substrate;
a first metal layer on a side of the substrate, wherein the first metal layer comprises one or more first scanning lines;
a second metal layer on a side of the first metal layer away from the substrate; and
a source drain layer arranged on a side of the second metal layer away from the first metal layer;
wherein the transition region comprises an invalid pixel region and a winding region, the winding region is between the invalid pixel region and the opening region, the invalid pixel region is provided with one or more compensation units, at least one of the one or more compensation units at least comprises a compensation wiring on the second metal layer, and a projection of the compensation wiring on the substrate overlaps with a projection of at least one of the one or more first scanning lines on the substrate.

2. The display panel according to claim 1, wherein at least one of the one or more compensation units further comprises a power supply high-potential signal line, at least part of the power supply high-potential signal line is on the second metal layer, and the power supply high-potential signal line is connected to the compensation wiring.

3. The display panel according to claim 2, wherein the source drain layer comprises a first source drain layer and a second source drain layer, the display panel further comprises a first planarization layer, the second source drain layer is on a side of the first source drain layer away from the second metal layer, the first planarization layer is between the first source drain layer and the second source drain layer, the power supply high-potential signal line comprises a first power supply high-potential signal line on the second metal layer and a second power supply high-potential signal line on the first source drain layer, the first power supply high-potential signal line is connected to the compensation wiring, and the second power supply high-potential signal line is connected to the compensation wiring throughout a via hole of the first planarization layer.

4. The display panel according to claim 3, wherein the display panel further comprises an interlayer insulating layer, the interlayer insulating layer is between the first source drain layer and the second metal layer, and at least one of the one or more compensation units further comprises:
a second scanning line arranged on the first metal layer and insulated from the first scanning line;
an initialization signal line comprising a first initialization signal line and a second initialization signal line, wherein the first initialization signal line is on the second metal layer, the second initialization signal line is on the first source drain layer, and the second initialization signal line is connected to the first initialization signal line throughout a via hole of the interlayer insulating layer;
a light-emitting control signal line on the first metal layer; and
a first data line on the second source drain layer.

5. The display panel according to claim 3, wherein the display panel further comprises a second data line in the winding region, the second data line comprises a first part on the second source drain layer and a second part on the first source drain layer, and the first part is connected to the second part throughout a via hole of the first planarization layer.

6. The display panel according to claim 5, wherein the display panel further comprises a first gate insulating layer, a second gate insulating layer, and an interlayer insulating layer, the first gate insulating layer is between the first metal layer and the substrate, the second gate insulating layer is between the first metal layer and the second metal layer, the interlayer insulating layer is between the second metal layer and the first source drain layer, the second data line further comprises a third part and a fourth part, the third part is on the second metal layer, the fourth part is on the first metal layer, the second part is connected to the third part throughout a via hole of the interlayer insulating layer, and the third part is connected to the fourth part throughout a via hole of the second gate insulating layer.

7. The display panel according to claim 1, wherein a display pixel is in the display region, an invalid pixel is in the invalid pixel region, and the invalid pixel is between the display pixel and at least one of the one or more compensation units.

8. The display panel according to claim 7, wherein the display panel further comprises an active layer, the active layer comprises an active pattern, and a projection area of the active pattern in the invalid pixel on the substrate is greater than a projection area of the active pattern in at least one of the one or more compensation units on the substrate.

9. The display panel according to claim 1, wherein the display region is around the opening region, and a shape of the opening region is at least one of a track shape, a circular shape, or a square shape.

10. The display panel according to claim 1, wherein along an arrangement direction of at least one of the one or more first scanning lines, one or more compensation units comprises a plurality of compensation units, the plurality of compensation units are respectively on two sides of the opening region.

11. The display panel according to claim 1, wherein the one or more first scanning lines comprises a plurality of rows of first scanning lines, and in the transition region, a corresponding overlapping area between a projection of each of the plurality of rows of first scanning lines on the substrate and a projection of the compensation wiring on the substrate is different.

12. The display panel according to claim 1, wherein the one or more first scanning lines comprises a plurality of rows of first scanning lines, and in the transition region, a number of one or more compensation units corresponding to each of the plurality of rows of first scanning lines is different.

13. A display apparatus, comprising a display panel and an electronic component, wherein the display panel comprises a display region, an opening region, and a transition region between the display region and the opening region, the display panel comprises:
a substrate;
a first metal layer on a side of the substrate, wherein the first metal layer comprises one or more first scanning lines;
a second metal layer on a side of the first metal layer away from the substrate; and
a source drain layer arranged on a side of the second metal layer away from the first metal layer;
wherein the transition region comprises an invalid pixel region and a winding region, the winding region is between the invalid pixel region and the opening region, the invalid pixel region is provided with one or more compensation units, at least one of the one or more compensation units at least comprises a compensation wiring on the second metal layer, and a projection of the compensation wiring on the substrate overlaps with a projection of at least one of the one or more first scanning lines on the substrate.

14. The display apparatus according to claim 13, wherein at least one of the one or more compensation units further comprises a power supply high-potential signal line, at least part of the power supply high-potential signal line is on the second metal layer, and the power supply high-potential signal line is connected to the compensation wiring.

15. The display apparatus according to claim 14, wherein the source drain layer comprises a first source drain layer and a second source drain layer, the display panel further comprises a first planarization layer, the second source drain layer is on a side of the first source drain layer away from the second metal layer, the first planarization layer is between the first source drain layer and the second source drain layer, the power supply high-potential signal line comprises a first power supply high-potential signal line on the second metal layer and a second power supply high-potential signal line on the first source drain layer, the first power supply high-potential signal line is connected to the compensation wiring, and the second power supply high-potential signal line is connected to the compensation wiring throughout a via hole of the first planarization layer.

16. The display apparatus according to claim 15, wherein the display panel further comprises an interlayer insulating layer, the interlayer insulating layer is between the first source drain layer and the second metal layer, and at least one of the one or more compensation units further comprises:
a second scanning line arranged on the first metal layer and insulated from the first scanning line;
an initialization signal line comprising a first initialization signal line and a second initialization signal line, wherein the first initialization signal line is on the second metal layer, the second initialization signal line is on the first source drain layer, and the second initialization signal line is connected to the first initialization signal line throughout a via hole of the interlayer insulating layer;
a light-emitting control signal line on the first metal layer; and
a first data line on the second source drain layer.

17. The display apparatus according to claim 15, wherein the display panel further comprises a second data line in the winding region, the second data line comprises a first part on the second source drain layer and a second part on the first source drain layer, and the first part is connected to the second part throughout a via hole of the first planarization layer.

18. The display apparatus according to claim 17, wherein the display panel further comprises a first gate insulating layer, a second gate insulating layer, and an interlayer insulating layer, the first gate insulating layer is between the first metal layer and the substrate, the second gate insulating layer is between the first metal layer and the second metal layer, the interlayer insulating layer is between the second metal layer and the first source drain layer, the second data line further comprises a third part and a fourth part, the third part is on the second metal layer, the fourth part is on the first metal layer, the second part is connected to the third part throughout a via hole of the interlayer insulating layer, and the third part is connected to the fourth part throughout a via hole of the second gate insulating layer.

19. The display apparatus according to claim 13, wherein a display pixel is in the display region, an invalid pixel is in the invalid pixel region, and the invalid pixel is between the display pixel and at least one of the one or more compensation units.

20. The display apparatus according to claim 19, wherein the display panel further comprises an active layer, the active layer comprises an active pattern, and a projection area of the active pattern in the invalid pixel on the substrate is greater than a projection area of the active pattern in at least one of the one or more compensation units on the substrate.
